(19) United States
(12) Patent Application Publication
(10) Pub. No.: US 2018/0158679 A1
(43) Pub. Date: Jun. 7, 2018

(54) High-Temperature Non-Stoichiometric Oxide Actuators

(71) Applicants: Krystyn J. VAN VLIET, Lexington, MA (US); Sean R. BISHOP, Silver Spring, MD (US); Harry L. TULLER, Wellesley, MA (US); Jessica G. SWALLOW, Cambridge, MA (US)

(72) Inventors: Krystyn J. VAN VLIET, Lexington, MA (US); Sean R. BISHOP, Silver Spring, MD (US); Harry L. TULLER, Wellesley, MA (US); Jessica G. SWALLOW, Cambridge, MA (US)

(21) Appl. No.: 15/828,848

(22) Filed: Dec. 1, 2017

Related U.S. Application Data
(60) Provisional application No. 62/429,143, filed on Dec. 2, 2016.
(60) Provisional application No. 62/429,297, filed on Dec. 2, 2016.

(51) Int. Cl. H01L 21/02

(52) U.S. Cl. CPC H01L 21/02483; H01L 21/02192

(57) ABSTRACT

A piezoelectric actuator expands or deflects in response to an applied voltage. Unfortunately, the voltage required to actuate a piezoelectric device is usually on the order of MV/cm. And most piezoelectric devices don't work well, if at all, at temperatures above 450° C. Fortunately, an oxide film actuator can work at temperatures above 450° C. and exhibits displacements of nanometers to microns at actuation voltages on the order of mV. Applying a voltage across an oxide film disposed on an ionically conducting substrate pumps oxygen ions into the oxide film, which in turn causes the oxide film to expand. This expansion can be controlled by varying the voltage based on the open-circuit potential across the oxide film and the substrate. Thanks to their low actuation voltages and ability to work at high temperatures, oxide-based actuators are suitable for applications from robotics to nuclear reactors.

### CROSS-REFERENCE TO RELATED APPLICATION(S)

This application claims the priority benefit, under 35 U.S.C. § 119(e), of U.S. Application No. 62/429,297, entitled “Dynamic Chemical Expansion of Thin Film Non-Stoichiometric Oxides at Extreme Temperatures” and filed on Dec. 2, 2016, and of U.S. Application No. 62/429,143, entitled “High Temperature Oxide Actuator” and filed on Dec. 2, 2016. Each of these applications is incorporated herein by reference in its entirety.

### GOVERNMENT SUPPORT

This invention was made with Government support under Grant No. DE-SC0002633 awarded by the Department of Energy. The Government has certain rights in the invention.

### BACKGROUND

Electrochemical energy conversion and storage devices including solid oxide fuel cells (SOFCs) and lithium ion batteries (LIBs) are enabled by materials known as “non-stoichiometric oxides” that contain very large concentrations of point defects such as oxygen or lithium vacancies. While this non-stoichiometry provides the functional properties of ionic conductivity or reactivity that make these materials useful, it also tends to couple to material volume through the effect of chemical expansion. Chemical expansion, or volume coupled to defect concentration, is in turn tied to mechanical variables including stress, strain, and elastic constants. This electrochemomechanical coupling, or interaction between functional properties, defect chemistry, and mechanical variables, can have important consequences for devices operated in extreme environments, where unexpected stress may lead to fracture, or well-engineered strain may enhance device efficiency. Such effects are particularly important in thin film devices, where strain engineering is within reach, undesired fracture can devastate performance, and defect chemistry and related properties can differ from bulk systems.

Further, materials that enable mechanical actuation and sensing in extreme environments are in high demand for applications including nuclear power control systems, jet turbine engines, and space exploration. The artificial muscles desired for these devices (e.g., electric motors and piezoelectrics) are often limited by material microstructural or compositional instability at high temperatures (>200° C.).

### SUMMARY

One embodiments of the present technology is an actuator comprising an ionically conducting substrate, a layer of non-stoichiometric oxide disposed on the ionically conducting substrate, a first electrode in electrical communication with the ionically conducting substrate, a second electrode in electrical communication with the layer of non-stoichiometric oxide, and a reference electrode in electrical communication with the ionically conducting substrate. In operation, the first electrode reduces gas-phase oxygen molecules to oxygen ions and pumps the oxygen ions through the ionically conducting substrate into the layer of non-stoichiometric oxide. These oxygen ions causing a change in thickness of the layer of non-stoichiometric oxide. The second electrode at least partially block the layer of non-stoichiometric oxide from emitting the oxygen ions. And the reference electrode senses an open-circuit potential between the first electrode and the second electrode. This open-circuit potential represent a gradient in oxygen pressure between the first electrode and the second electrode.

The ionically conducting substrate may comprise yttria stabilized zirconia (YSZ) and may have a thickness of about 50 μm to about 10 mm.

The layer of non-stoichiometric oxide may comprise PrxCe1-xO2-δ, CeO2-δ, Sr(Ti,Fe)O3-δ, (La,Sr)(Co,Fe)O3-δ, or LaMnO3. The layer of non-stoichiometric oxide may have a thickness of about 50 nm and about 1 μm when the bias voltage is 0 volts. Its width (lateral dimension) may be different than the ionically conducting substrate's width. The layer of non-stoichiometric oxide can be chemically and physically stable at a temperature of 450 degrees Celsius. The layer of non-stoichiometric oxide can exhibit an out-of-plane strain of up to about 0.5%. In operation, its change in thickness can be due to a strain-only expansion and may be about 0.25 nm to about 5 nm.

The first electrode may comprise a porous metal or a mixed conductor. The reference electrode can be disposed about a circumference of the ionically conducting substrate. In some cases, the first electrode and the reference electrode are disposed on a surface of the ionically conducting substrate.

Another embodiment of the present technology is a method of actuating an actuator by applying a bias voltage (e.g., of about 10 mV to about 10 V) to a layer of non-stoichiometric oxide disposed on an ionically conducting substrate. The bias voltage causes a change in oxygen content of the layer of non-stoichiometric oxide. This change in oxygen content of the layer of non-stoichiometric oxide in turn causes a change in a thickness, interfacial stress, or deflection of the layer of non-stoichiometric oxide. The method also includes sensing an open-circuit potential across the layer of non-stoichiometric oxide and the ionically conducting substrate. If desired, the bias voltage may be changed based on the open-circuit potential.

In some cases, applying the bias voltage causes the layer of non-stoichiometric oxide to exhibit an out-of-plane strain of up to about 0.5%. Applying the bias voltage may also cause the layer of non-stoichiometric oxide to bend at least a portion of the ionically conducting substrate.

For cases in which the bias voltage causes the layer of non-stoichiometric oxide to change in thickness, the change in thickness may be due to a strain-only expansion, may be at least about 1 nm, or both.

If desired, the layer of non-stoichiometric oxide may be heated to a temperature of at least about 450 degrees Celsius (° C.) during operation.

Another embodiment includes an actuator with an ionically conducting substrate, a layer of non-stoichiometric oxide disposed on the ionically conducting substrate, and a pair of electrodes. The layer of non-stoichiometric oxide is chemically and physically stable at a temperature of 450 degrees Celsius. The electrodes are configured to apply a bias voltage across the layer of non-stoichiometric oxide and the ionically conducting substrate. This bias voltage causes a change in oxygen content of the layer of non-stoichiometric oxide. And this change in oxygen content of the layer of non-stoichiometric oxide causes a change in at least one of a thickness, interfacial stress, or deflection of the layer of non-stoichiometric oxide.

Yet another embodiment includes an actuator with an ionically conducting substrate, a layer of non-stoichiometric oxide disposed on the ionically conducting substrate, and a pair of electrodes. In this embodiment, the layer of non-stoichiometric oxide includes a fluorite-structured oxide. The electrodes are configured to apply a bias voltage across the layer of non-stoichiometric oxide and the ionically conducting substrate. This bias voltage causes a change in oxygen content of the layer of non-stoichiometric oxide. And this change in oxygen content of the layer of non-stoichiometric oxide causes a change in at least one of a thickness, interfacial stress, or deflection of the layer of non-stoichiometric oxide.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows a generalized equation representing chemical expansion in non-stoichiometric oxides based on oxygen vacancy concentration and charge balance.

FIGS. 1B, 1C, and 1D illustrate changes in lattice structure and chemical expansion in non-stoichiometric oxides resulting from the equation in FIG. 1A.

FIG. 2A shows a plot of Young's modulus as a function of lattice parameter in the non-stoichiometric oxide GDC.

FIG. 2B shows a plot of a quantification of ionic conductivity of YSZ as a function of factor of lattice constant mismatch in the substrates used, corresponding to variation in strain.

FIG. 2C is a schematic illustration of the electrochemomechanical interactions in a layered nonstoichiometric oxide film-on-substrate actuator based on oxygen vacancy content.

FIG. 3 is an illustration of the crystal structure of a non-stoichiometric, fluorite-structured oxide, PCO.

FIG. 4 is a plot showing the temperature dependence of thermal and chemical expansion in PCO.

FIG. 5 is a plot showing the dependence of oxygen vacancy concentration of PCO on oxygen partial pressure at different temperatures.

FIG. 6A is a schematic illustration of an example nonstoichiometric oxide actuator.

FIG. 6B shows the actuator of FIG. 6A deflecting in response to an alternating bias voltage.

FIG. 7 shows an example method actuating a nonstoichiometric oxide actuator.

FIG. 8 is a schematic illustration of an example nonstoichiometric oxide actuator whose oxide layer is smaller in area than the ionically conducting substrate.

FIG. 9 is a plot showing measurements of strain-only displacement in an example actuator such as the one shown in FIG. 8.

FIG. 10 is a schematic illustration of a side view of an example actuator, illustrating position-based deflection in response to applied bias.

FIG. 11 is a schematic illustration of the top-view of an example actuator, showing the geometry of the actuator overlaid with probe positions for testing deflection amplitude as a function of position across the actuator surface.

FIG. 12 is a plot showing amplitude of displacement experimentally measured in an example actuator, at the probe positions shown in FIG. 11, as a function of distance from center of the actuator.

FIG. 13 shows representative Arrhenius plots estimating the activation energy for YSZ diffusion and PCO chemical capacitance based on the values of τ/D0 (inverse deflection rate) and D0 (deflection magnitude), respectively.

FIG. 14 shows a plot of the equilibrium magnitude of displacement D0 of a probe, used to measure displacement of an example actuator, as a function of temperature, applied bias amplitude E0, and film thickness.

FIG. 15 shows a plot quantifying the out-of-plane strain E and non-stoichiometry change Δδ as a function of applied bias at several temperatures for a constrained PCO thin film as predicted by a defect model for PCO. Structural deflection is amplified by a factor of five, with respect to film thickness change alone, for this specific example.

FIG. 16 shows a plot of experimentally measured deflection amplitude D0, of an example actuator, as a function of predicted change in thickness of the film of the non-stoichiometric oxide layer of the actuator, the predicted values being calculated using chemical strains shown in FIG. 15 for the set of experimental measurements shown in FIG. 14.

FIG. 17 shows Lissajous plots of displacement from experimental measurement as a function of applied bias for two Voffset conditions corresponding to varying values of effective partial pressure of oxygen, (pO_{2, eff}) using example actuators with PCO.

FIGS. 18 and 19 show Lissajous plots of experimental measurements of displacement and charge, respectively, as a function of applied bias for three Voffset conditions corresponding to varying values of effective partial pressure of oxygen, (pO2,eff) using example actuators with perovskite-structured oxide (STF).

### DETAILED DESCRIPTION

### Introduction

Non-stoichiometric compounds are compounds with non-integer values of elemental composition, generated due to the presence of imperfections in their crystal lattice structure, such as too few or too many atoms packed into the crystal lattice. They exhibit interesting chemical or electrical properties. Non-stoichiometric oxides are oxides with very large concentrations of point defects, such as oxygen or lithium vacancies. Example non-stoichiometric oxides include, but are not limited to: fluorite-structured oxides containing O, lanthanide elements including Ce and Pr, and transition metal elements such as Fe; and Perovskite-structured oxides, such as LiBaF₃ and LaMnO₃. The non-stoichiometry imparts these materials with functional properties of ionic conductivity or reactivity that can be used in several applications, such as electrodes and/or electrolytes in solid oxide fuel cells (SOFCs) and actuators as described here.

For example, non-stoichiometric oxides can undergo chemical expansion. That is, their volume can be coupled to defect concentration, which is in turn tied to mechanical variables including stress, strain, and elastic constants. This electrochemomechanical coupling, or interaction between functional properties, defect chemistry, and mechanical variables, can be used in actuators and sensors. Actuators and sensors that use electrochemomechanical coupling can operate in extreme environments, including environments with high temperatures (e.g., >600° C.).

Unlike piezoelectric actuation, chemical-expansion-driven actuation with oxide films works well at high temperatures and provides large displacements or deflections at relatively small voltages. For example, an oxide file actuator can undergo tens of nm cyclic actuation at hundreds of mV applied bias under sustained 650° C. environments. This performance is difficult, if not impossible, with current piezoelectric actuators. Additionally, the significant actuation amplitude observed in such extreme environments is repeatable for many cycles and on different samples, and can be tuned further by adjusting film thickness, operating temperature, or applied bias range.

### Chemical Expansion in Non-Stoichiometric Oxides

Chemical expansion is a coupling between material volume and point defect concentration. Chemical expansion can occur for many kinds of defects. As an example, the chemical expansion that occurs in association with oxygen vacancy formation is exemplified here following the oxygen vacancy formation reaction of a model non-stoichiometric fluorite-structured oxide PrₓCe₁₋ₓO_{2-δ} (PCO):

2Pr_{Ce}^{x}+O_{O}^{x}↔2Pr′_{Ce}+V_{O}^{••}+½O_{2(g)} (1)

Here, Pr×Ce and Pr′Ce denote Pr4+ and Pr3+, respectively, on Ce sites; O_{O}^{x} denotes O₂⁻ on an oxygen site; and V_{O}^{••} denotes a vacancy on an oxygen site. Chemical expansion has been observed in many other oxide conductors, including doped and undoped CeO_{2-δ}, Sr(Ti,Fe)O_{3-δ} (STF), (La,Sr)(Co,Fe)O_{3-δ} (LSCF), and LaMnO₃ (LMO). Chemical expansion from the functional and mechanical properties of non-stoichiometric oxides can lead to mechanical deflection and/or mechanical strain, depending on the materials.

In general, chemical expansion is defined using a chemical expansion coefficient α_{c} that relates chemical strain ∈ to a change in oxygen vacancy concentration Δδ according to Eq. 2:

ε=α_{c}Δδ (2)

This coefficient is generally assumed to be independent of temperature, but this is not always the case. Additionally, the value of α_{c} can vary between bulk and thin film oxide forms.

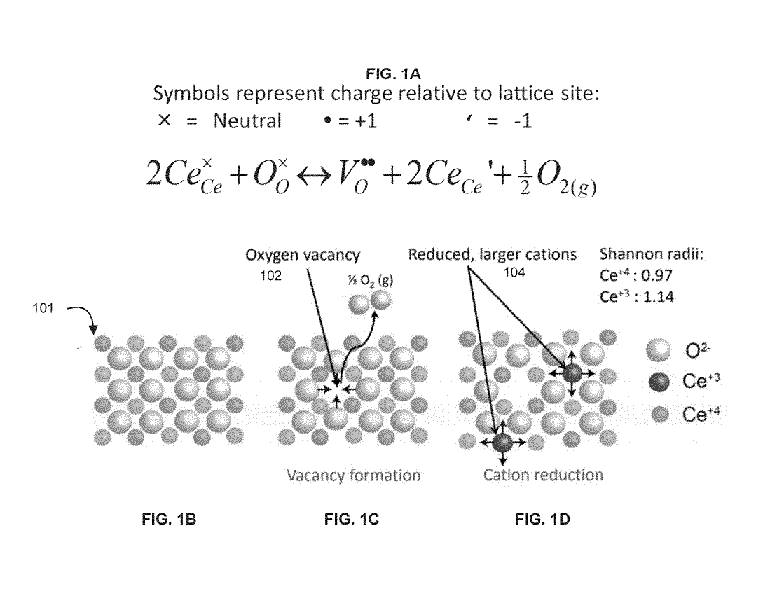

FIG. 1A illustrates an example equation representing chemical expansion in a non-stoichiometric oxide, modulated by oxygen activity. FIG. 1B illustrates the crystal lattice structure of an example non-stoichiometric oxide layer 101, with spheres representing Ce′ cations and O²⁻ anions. FIGS. 1C and 1D illustrate the process of formation of oxygen vacancy (102) V_{O}^{••} which can lead to contraction and the reduction of Ce+4 to Ce+3 cations to form reduced cations (104) with increased diameter that can result in expansion of the non-stoichiometric oxide material, respectively.

### Electrochemomechanical Coupling

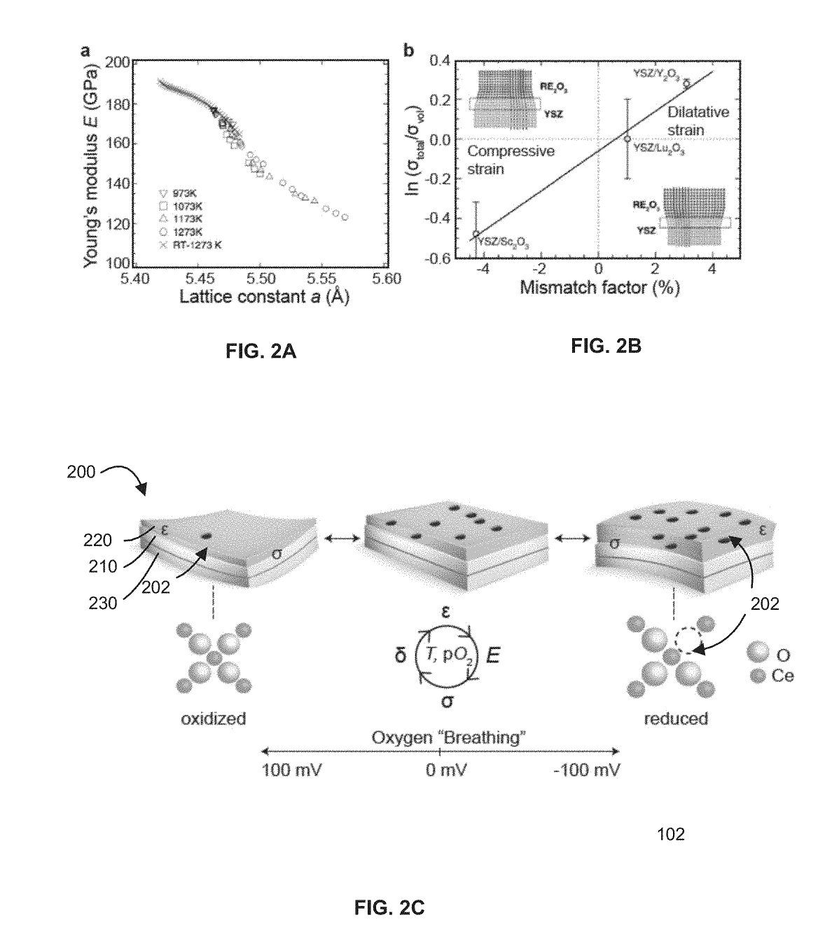

Thermochemical expansion in non-stoichiometric oxides contributes to changes in mechanical properties and stability of materials. Without being bound by any particular theory, increased lattice parameter due to thermal and chemical expansion is expected to cause decreased mechanical stiffness as shown in FIG. 2A, due to the increased bond length and decreased effective resistance to further bond stretching upon such expansion. This has been observed experimentally for bulk oxide materials including (Gd, Ce)O_{2-δ} (Gd-doped ceria, or GDC). With increased lattice parameter, bond strength decreases in crystalline materials, resulting in decreased elastic modulus. This changes the actual stress state present at oxide interfaces at elevated temperatures and under reducing conditions. Not only does material volume change in situ, but the mechanical stiffness varies as well. The plot in FIG. 2A illustrates how, in bulk Gd_{0.1}Ce_{0.9}O₂₋₈, increased lattice parameter due to chemical and thermal expansion is correlated with decreased Young's elastic modulus.

Chemical expansion can also change the electrical properties of materials. The plot in FIG. 2B shows how varying tensile lattice strain can enhance the ionic conductivity σₜₒₜ of yttria stabilized zirconia (YSZ) relative to the bulk value σᵥₒₗ when grown epitaxially on mismatched substrates.

### Interplay Between Strain States, Oxygen Exchange Reactivity and Vacancy Migration

Mechanical strain can affect both the oxygen exchange reactivity and/or ionic conductivity of oxides including YSZ, GDC, (La,Sr)CoO₃ (LSC), and Nd₂NiO_{4+δ}. Given the close association between chemistry and mechanics in ionically conductive non-stoichiometric oxides, strain may be used to influence chemistry just as chemical composition gradients produce strain in these materials. In several non-stoichiometric oxides, both the oxygen vacancy formation energy and oxygen vacancy migration energy can significantly decrease upon application of tensile strain, potentially increasing the oxygen reduction reactivity and oxygen diffusivity, respectively. On the other hand, tensile strain has been shown to simultaneously decrease the mobility of adsorbed oxygen atoms in the case of LaCoO₃, indicating that lattice strain can cause competing effects on the oxygen reduction reaction (ORR) activity.

Related to the effect of strain on defect formation and migration energies is the theory of the “activation volume.” Generally speaking, the rate constant k of a typical process shows Arrhenius behavior of the type described by Eq. 3, where ΔG^{‡} is the Gibb's free energy of activation for the process, which can be broken into an entropic contribution, −TΔS^{‡}, a contribution from the elastic strain energy of activation (where is the activation strain of the process, and σᵢⱼ is the stress) and a contribution from the internal energy, ΔU^{‡}.

$$k = {k}_{0} exp ( \frac{- Δ {G}^{‡}}{RT} ) = {k}_{0} exp ( \frac{Δ {S}^{‡}}{R} ) exp ( \frac{{ɛ}_{ij}^{‡} {σ}_{ij} Ω}{RT} ) exp ( \frac{- Δ {U}^{‡}}{RT} ) \qquad ( 3 )$$

Such a rate law can be applied to the process of vacancy migration to a neighboring lattice site. In the simplified case of hydrostatic stress, the rate law then becomes Eq. 4 where P is the pressure and Ω^{‡} is the activation volume

$$k = {k}_{0} exp ( \frac{Δ {S}^{‡}}{R} ) exp ( \frac{- P {Ω}^{‡}}{RT} ) exp ( \frac{- Δ {U}^{‡}}{RT} ) \qquad ( 4 )$$

If the activation entropy and internal energy remain insensitive to pressure, then the activation volume can be determined from the pressure dependence of the rate, according to Eq. 5.

$${Ω}^{‡} = - RT ( \frac{\partial log k}{\partial P} ) \qquad ( 5 )$$

Thus, applying stress to the material causes a change in the rate of vacancy migration corresponding to a change in the activation free energy of the process. In general, it has been hypothesized that a tensile strain lowers the vacancy migration energy by decreasing the activation free energy, and therefore enhances the rate of vacancy migration, corresponding to an increase in ionic conductivity. The reverse effect is expected for a compressive strain. Experimental studies have confirmed this predicted trend to varying degrees for a few non-stoichiometric oxides. This effect is highlighted for YSZ in FIG. 2B. This relationship between strain states and ionic conductivity could be used to lower operating temperatures by enhancing kinetics through mechanical cues.

As illustrated schematically in FIGS. 2A and 2B, not only can chemical expansion adjust in situ stress states in multilayer structures, but mechanical properties including mechanical stiffness may depend on defect chemistry as well. These examples illustrate how lattice strain is closely coupled to both the composition (defect concentration) of non-stoichiometric oxides and their functional properties, including ionic conductivity and oxygen exchange reactivity. Defect concentrations also depend on environmental conditions including temperature and effective oxygen partial pressure, and are coupled to material volume via chemical expansion.

### Thin-Film Oxides

Thin films do not necessarily exhibit identical defect chemistry, symmetry, or charge transport to their bulk counterparts. For example, it has been observed that nominally equivalent compositions of several non-stoichiometric oxides can show significantly differing point defect concentrations in film forms as opposed to bulk forms under the same conditions of pO₂ and temperature. Such discrepancies have been attributed to, for example, space charge layers at surfaces, interfaces, or grain boundaries that occupy a much larger volume fraction in thin films than they do in bulk. Space charge is in turn expected to impact charge transport, causing, for example, grain-size dependent ionic conductivity that has been observed experimentally in nanocrystalline films.

Additionally, films of nominally cubic perovskite or fluorite oxides may deform anisotropically due to biaxial stress states that could cause, for example, anisotropic chemical expansion. In the case of highly strained ceria films, enhanced oxygen storage capacity has been observed and attributed to such anisotropic lattice distortion. These results highlight the point that thin film and bulk oxides of theoretically identical composition in practice can have varied point defect concentrations which couple to functional and mechanical material properties. The interrelated nature of defect chemistry, stress, strain, mechanical stiffness, charge transport, and reactivity in these materials makes them suitable for use in actuators that operate at high temperatures and under reducing oxygen partial pressures.

Furthermore, the underlying process of chemical expansion can be controlled not only directly by charge localization but also indirectly by adjusting the oxygen partial pressure pO₂ and/or by applying an electrical bias, as described in detail below.

### Volume Change in a Layered Non-Stoichiometric Film-On-Substrate System

FIG. 2C shows a schematic of electrochemomechanical interactions leading to volume change, resulting from oxygen “breathing,” in a layered non-stoichiometric oxide film-on-substrate system 200. A film 220 on an oxide conducting substrate 210 undergoes chemical expansion when its concentration δ of oxygen vacancies 202 (dark holes) is adjusted either by applying electrical bias or by modulating oxygen partial pressure O₂. The resulting chemical strain ε causes a mechanical stress a at the interface between the film 220 and the substrate 210, along with film thickness change. Additionally, the film elastic modulus E changes when the film undergoes chemical expansion. The mechanical stress at the interface is a function of both ε and E, and can lead to substrate deflection. Thus, environmental conditions, mechanics, and defect chemistry are interrelated in the oxide film in ways that may differ from bulk counterparts. In turn, transport and reactivity properties are also coupled to E, 6, and a.

Put differently, biasing the non-stoichiometric film 220 on an oxide ion conducting substrate 210 with respect to the reference electrode 230 with an alternating voltage causes the film 2200 to oscillate between cathodic (negative, reducing) and anodic (positive, oxidizing) conditions. Under anodic bias, the film 220 breathes oxygen in, producing an overall contraction and reduction in film thickness and corresponding negative substrate deflection. Under cathodic bias, the film 220 releases oxygen, resulting in increased oxide ion vacancy content (dark holes 202) and a corresponding increase in film thickness and positive substrate deflection.

The electrochemically driven breathing response of non-stoichiometric oxide films presents advantages for high temperature actuation. The predicted strain of these oxides at temperatures above 550° C. is ˜0.1-0.2% for applied biases of ˜0.1 V. Thus, sensors or actuators based on these materials can operate at much lower voltages than a typical high temperature piezoelectric device, which requires electric fields on the order of MV/cm to produce strains of the same scale.

For example, compare a 1 μm film of a piezoelectric material with strain coefficient d₁₁ of 10 pC/N (about the highest currently available for piezoelectrics operating above 400° C.) to a PCO-YSZ device with the same film thickness. For the piezoelectric device, 100 V of electrical potential are needed to achieve a strain of 0.1%. The PCO device exhibits the same strain at 100 mV. If both devices are subjected to the same 100 mV, then the achievable actuator “velocity” (frequency×displacement) is roughly the same when the piezoelectric is operated at 1 kHz and the PCO device is operated at 1 Hz. Finally, the interfacial stress generated in response to equal applied bias in these devices of comparable size likewise differs by three orders of magnitude if elastic properties are held constant allowing enhanced deflection-based actuation.

A Model Non-Stoichiometric Oxide Film: PrₓCe₁₋ₓO (PCO)

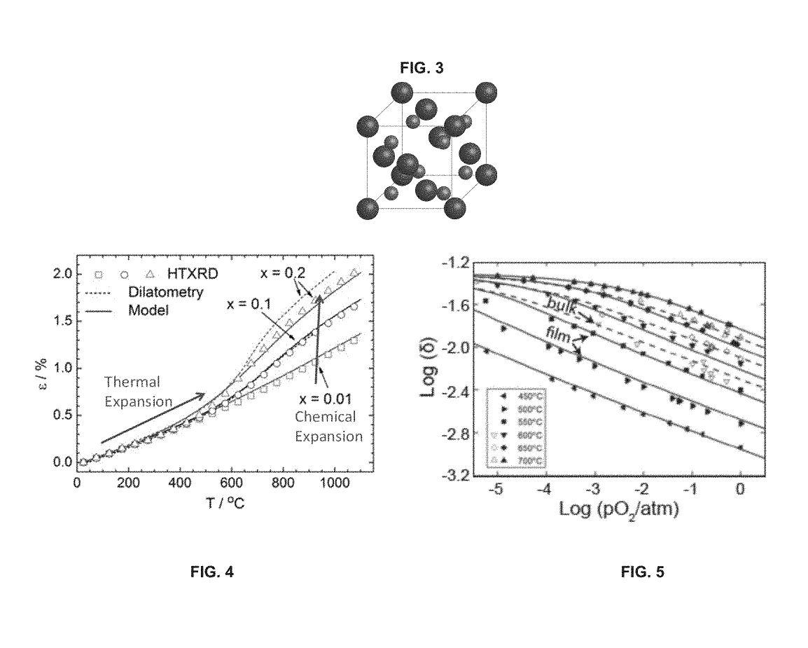

PrₓCe₁₋ₓO_{2-δ} (PCO) is a fluorite structured oxide that undergoes large changes in non-stoichiometry and corresponding oxygen vacancy concentration δ in both cathodic and anodic conditions, with significant chemical expansion. The fluorite structured lattice of PCO is illustrated in FIG. 3. Generally for PCO, increased δ is correlated to increased Pr′_{Ce} and lattice parameter a. Large changes of δ in cathodic conditions are facilitated by the ease of Pr reduction according to Eq. 1, and thus larger volume fractions of Pr within the oxide generally increase electrochemical reducibility in these conditions. The thermal and chemical expansion coefficients of PCO have been measured at 1.2×10⁻⁵ and 0.084-0.087 Δε/Δδ. The chemical expansion coefficient varies slightly between bulk and thin film forms of PCO, as described above. Due to the mixed-valent nature of Pr, PCO is a mixed ionic-electronic conductor under relatively oxidizing conditions.

As described above, the oxygen vacancy concentration δ of PCO in thin films supported on ionically conducting substrates can be controlled both by changing the surrounding atmosphere and by application of electrical bias. The degree of chemical expansion in PCO can also be changed by dopant concentration and temperature conditions. FIG. 4 shows experimental measurements of thermochemical strain E, measured through dilatometry, and predicted changes in thermochemical strain through modelling studies of PCO as a function of temperature, for several compositions with varying dopant concentration x. Above 500° C., PCO undergoes chemical expansion with increased oxygen vacancy concentration correlated with increased dopant concentration x.

FIG. 5 shows how the oxygen vacancy concentration δ of PCO depends on the oxygen partial pressure and temperature T, and is also different for thin film (solid lines, filled symbols) and bulk (dashed lines, open symbols) samples with equivalent x under the same conditions of T and pO2. Thin films of PCO exhibit larger δ than equivalent compositions of bulk PCO in the same environmental conditions.

Additionally, PCO was studied by simultaneous optical and chemical capacitance measurements to demonstrate a non-contact way of detecting δ in thin films that exhibit an optically active impurity band coupled to δ. PCO has also been investigated in several computational studies, including computations of vacancy formation and migration energies estimated using DFT and Monte Carlo simulations. PCO serves as a good non-stoichiometric oxide film for an actuator because of its easily controlled defect content under relatively easy-to-access experimental conditions, and the predictive power of the defect chemistry model.

### Chemical Expansion and Electrical Control of Expansion in PCO

One method of controlling the chemical expansion in PCO is enabled by the ability to electrically pump oxygen into a PCO film through a construction called the “effective pO₂”. The oxygen vacancy formation, which couples to lattice dilation, is favored by low oxygen partial pressure environments as described above in Eq. (1), reproduced here:

2Pr_{Ce}^{x}+O_{O}^{x}↔2Pr′_{Ce}+V_{O}^{••}+½O_{2(g)} (1)

This can be seen from the mass action relation for Eq. 6, where OH, ΔH_{r,Pr} is the enthalpy of reaction, k_{r,Pr} is a pre-exponential term, and K_{r,Pr} is the equilibrium constant of this reaction:

$$\frac{{[ {Pr}_{Ce}^{′} ]}^{2} [ {V}_{O}^{\cdot \cdot } ] {pO}_{2}^{1 / 2}}{{[ {Pr}_{Ce}^{\times } ]}^{2} [ {O}_{O}^{\times } ]} = {k}_{r , Pr} exp ( \frac{- Δ {H}_{r , Pr}}{kT} ) = {K}_{r , Pr} \qquad ( 6 )$$

In an electrochemical system, the oxygen vacancy concentration [V_{O}^{••}] is determined based on the effective chemical potential of oxygen μ_{O}_{₂}_{,eff}, which can be shifted away from the chemical potential of oxygen in the gas phase, μ_{O}_{₂}_{,g} by an electrical bias ΔE according to the Nernst relation Eq. 7:

μ_{O}_{₂}_{,eff}=μ_{O}_{₂}_{,g}+4eΔE (7)

Thus, for an oxide film that is electrically biased relative to a reference state in equilibrium with a gas phase, the effective oxygen partial pressure pO_{2,eff} can be defined as:

$${p}_{{O}_{2} , eff} = {p}_{{O}_{2} , g} exp ( \frac{4 e Δ E}{kT} ) \qquad ( 8 )$$

Chemical capacitance is defined as the chemical storage capacity of a material under a potential, and results from formation and annihilation of oxygen vacancies and Pr′_{Ce} in PCO. Equation 9 relates chemical capacitance C_{chem} to pO_{2,eff}, film volume V_{film}, and [V_{O}^{••}]:

$${C}_{chem} = - \frac{8 {e}^{2} {V}_{film}}{kT} ( {pO}_{2 , eff} \frac{δ [ {V}_{O}^{\cdot \cdot } ]}{δ {pO}_{2 , eff}} ) \qquad ( 9 )$$

By rearranging Eq. 9 and integrating with respect to pO_{2,eff}, [V_{O}^{••}] may be determined if a reference state pO_{2,eff} is available for which [V_{O}^{••}] is known. This results in Eq. 10:

$$[ {V}_{O}^{\cdot \cdot } ] ( {pO}_{2 , eff} ) = \frac{kT}{8 {e}^{2} {V}_{film}} \int {C}_{chem} d ln {pO}_{2 , eff} + [ {V}_{O}^{\cdot \cdot } ] ( {pO}_{2 , eff} ) \qquad ( 10 )$$

In the high pO₂ regime, solving Eq. 10 gives a linear relationship between chemical capacitance and [V_{O}^{••}]. This result has been well-established through prior electrochemical measurements coupled to defect modeling for PCO.

One consequence of this result is that electrical bias can be used to “pump” oxygen into and out of a PCO film grown on an ionically conducting substrate. This “electrochemical breathing” enables instantaneous adjustment of an oxide's equilibrium [V_{O}^{••}] or δ, meaning that all coupled effects (including volume change through chemical expansion) may also be driven rapidly via electrical modulation. In principle, the same approach can be used to pump oxygen or other mobile ionic species into or out of any conducting oxide so long as leakage currents (e.g., due to gas-phase reactions) are small enough. Put differently, the leakage should be smaller than the charge storage. In other words, the surface exchange rate (gas exchange for PCO) should be slower than the rate of oxygen pumping into and out of the sample (controlled by substrate ionic conductivity in the PCO-on-YSZ actuator described below). For example, the leakage currents may be at least an order of magnitude less than the current due to ionic transport.

### Actuators Based on Thin-Film Oxides

Electrical control of chemical expansion in non-stoichiometric oxide layers like PCO can be used for actuators and sensors. For instance, an actuator may have a non-stoichiometric oxide layer disposed on an ionically conducting substrate. Applying an electrical bias voltage to the oxide layer through appropriately connected electrodes results in a controlled chemical expansion or chemical strain in the non-stoichiometric layer.

### An Example Actuator

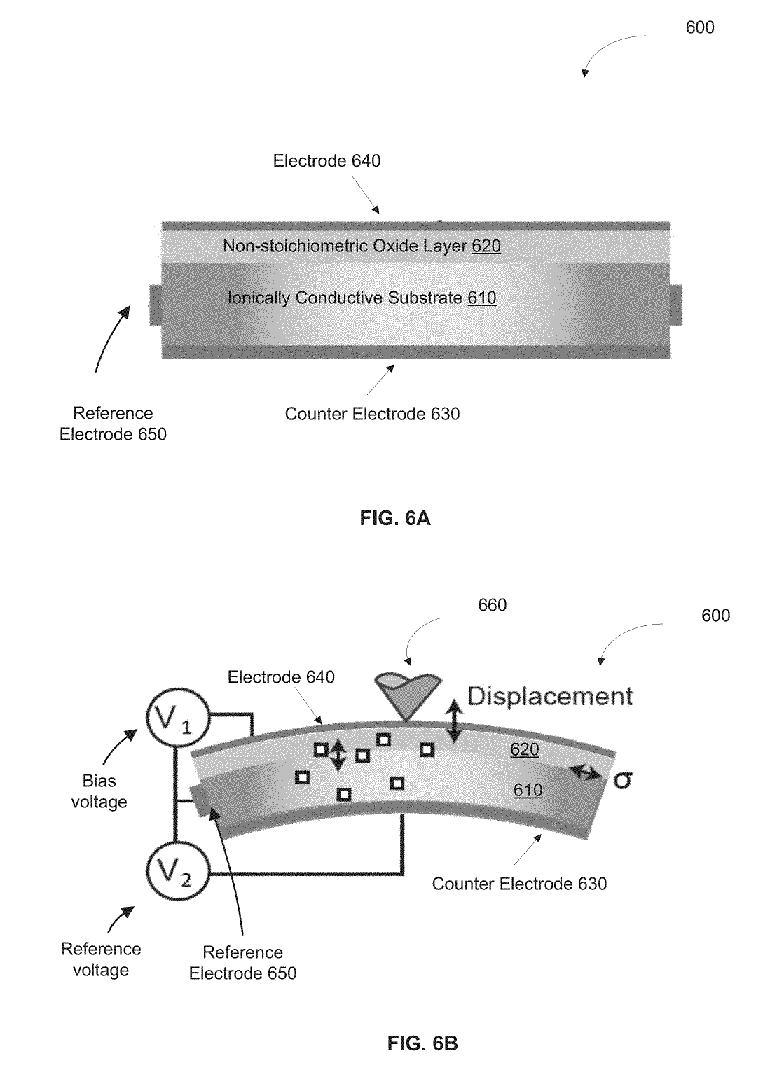

FIG. 6A shows an example high-temperature, non-stoichiometric oxide actuator 600 comprising an ionically conductive substrate layer 610, a non-stoichiometric oxide layer 620 disposed on the ionically conductive substrate layer 610, a first (counter) electrode 630 and an optional reference electrode 650 in contact with the ionically conductive substrate layer 610, and a second electrode 640 in contact with the non-stoichiometric oxide layer 620. The first and second electrodes 630, 640 are configured to apply a bias voltage to the layer of non-stoichiometric oxide 620.

The non-stoichiometric layer 620 can be formed of a film of non-stoichiometric oxide of desired thickness, which can range from 50 nm to 1 μm (e.g., 100 nm, 250 nm, 500 nm, or 750 nm) when there is no applied voltage. This oxide layer may be chemically and physically stable at temperatures of 450° C. and above. It can be grown epitaxially over an ionically conductive substrate layer 610 of predetermined dimensions. The non-stoichiometric oxide layer 620 can be made from non-stoichiometric oxides such as fluorites like PCO, undoped ceria or CeO_{2-δ}, Sr(Ti,Fe)O_{3-δ} (STF), (La,Sr)(Co,Fe)O_{3-δ} (LSCF), Sm-doped ceria, undoped ceria in reducing conditions, and LaMnO₃(LMO). The non-stoichiometric oxide layer 620 can also be made other suitable fluorites and perovskites that undergo chemical expansion, for example, using fluorites including elements containing Zr, Pr, Tb, and Eu; transition metal perovskites, pyrochlores, etc.

The ionically conductive substrate 610 (also referred to as the electrolyte) can be made from materials such as fluorite structured oxides like yttria stabilized zirconia (YSZ), oxide conductors like Gadolinium-doped ceria (GDC), perovskites like Lanthanum strontium gallium magnesium oxide (LSGM) and pyrocholores, etc. The ionically conductive substrate 610 can have a thickness in the range of about 50-100 nm to about a few millimeters (e.g., 100 nm, 250 nm, 500 nm, 750 nm, 1 mm, 1.5 mm, 2 mm, and so on).

The first electrode 630 can be a porous metal or mixed conductor electrode that conducts ions, oxygen, and electrons. The first electrode 630 is in electrical communication with the ionically conducting substrate 610. In operation, applying a voltage to the first electrode 630 reduces gas-phase oxygen molecules and pumps oxygen ions through the ionically conducting substrate 610 into the layer of non-stoichiometric oxide 620.

The second electrode 640 can be a non-porous material (e.g., solid metal) that hinders or at least partially blocks the non-stoichiometric oxide layer 620 from emitting the oxygen ions. For instance, the second electrode 640 may have an oxygen exchange coefficient or characteristic time for oxygen exchange that is about ten times slower than the operation frequency of the actuator. This traps the oxygen ions in the non-stoichiometric oxide layer 620, causing the non-stoichiometric oxide layer 620 to expand.

In some embodiments, the actuator 600 can also include the reference electrode 650, in electrical communication with the ionically conductive substrate layer 610. In operation, the reference electrode 650 is used to sense an open-circuit potential between the first electrode 630 and the second electrode 640. This open-circuit potential represents a gradient in oxygen pressure between the first electrode 630 and the second electrode 640 and can be used to set the desired amount of expansion or contraction of the actuator 600. The reference electrode 650 is electrically isolated from the second electrode 640 and the oxide layer 620; that is, it is configured such that it cannot short-circuit the first electrode 630 and second electrode 640. For example, the reference electrode 650 can be a ring around the circumference of the substrate 610 as shown in FIG. 6A or around first electrode 630 on the surface of the substrate 610. This configuration of the reference electrode 650 can be key to reproducible implantation of the actuator.

In some embodiments of the actuator 600, the non-stoichiometric layer 620 and the ionically conductive substrate 610 can have the same width. In some other embodiments of the actuator 600, they can have different widths. For example, the non-stoichiometric layer 620 can have a smaller width compared to the width of the ionically conductive substrate 610.

The non-stoichiometric layer 620 can exhibit a change in thickness or a deflection of at least 1 nm and sometimes a change of up to 25 μm. This change in thickness causes the actuator 600 to change in thickness and/or deflect. In some embodiments of the actuator 600, the non-stoichiometric layer 620 can be configured to exhibit an out-of-plane strain of up to about 0.5%. The out-of-plane strain depends on the expansion coefficient of the material and the applied bias voltage.

The electrodes 630 and 640 can each be porous platinum electrode layers of suitable dimensions. The porous Pt electrode layer 630, for example, can extend over the width of the ionically conductive substrate 610 with a suitable thickness and the porous Pt electrode layer 640 can extend over the width of the non-stoichiometric oxide layer 620. In example actuators used for some experiments described below, the porous Pt layers, as the current collector electrode 640 for the PCO working electrode and as the counter electrode 630 were prepared by a combination of Pt paste and reactive sputtering on the PCO film and the opposite PCO-free substrate surface, with thicknesses of 83±4 nm and 159±31 nm, respectively.

Unlike other actuators, the actuator 600 in FIG. 6A exhibits chemical and physical stability when operating at temperatures greater than 450° C. In other words, the actuator 600 works repeatedly over long times and many cycles at high temperatures. For instance, its oxide actuation amplitude may change by less than 10% (or 15% or 20%) over hundreds or thousands of cycles within its operation bias range.

### Making a Thin-Film Oxide Actuator

The actuator 600 shown in FIG. 6A can be made according to any of a variety of suitable processes. For instance, the actuators used for experimental results described below comprised of films of Pr_{0.1}Ce_{0.9}O_{2-δ} (PCO) with a desired thicknesses of 371±11, 600±20, 883±13, or 1018±26 nm grown by pulsed laser deposition (PLD) on single crystal (100) YSZ substrates (MTI Corporation, Richmond, Calif.) of dimensions 10×10×1.0 mm³. Details of the PLD film growth and characterization for thickness and crystal structure by profilometry and X-ray diffraction follow.

Substrates were heated to 500° C. after reaching a base pressure of 8.5×10⁻⁶ torr, and a dense PCO target was ablated by using a 248 nm wavelength coherent COMPex Pro 205 KrF eximer laser (Santa Clara, Calif.) with an 8 Hz laser repetition rate at 400 mJ/pulse. An oxygen partial pressure of 10 mTorr was maintained during both the deposition and cooling steps (5° C./min). Post-annealing with a sudden increase in oxygen partial pressure at the deposition temperature in the PLD chamber was not included to avoid severe cracks and delamination caused by rapid changes in film volume. Instead, the samples were heated to high temperatures and held there before being cooled at 5° C./min. Except in the case of the 600 nm film which was measured by profilometry, film thickness was measured by scanning electron microscopy of films that were cross-sectioned either by cleaving or focused ion beam (FIB) milling (Helios Nanolab 600 Dual Beam Focused Ion Beam Milling System, FEI, Burlington, Mass.). Film crystallographic texture was confirmed by X-ray diffraction (X'Pert Pro MPD PANalytical diffractometer) from 2θ-ω coupled scans of the films, which indicated a highly oriented (100) texture. Film surface roughness (root mean square) and grain size were 1.3±0.2 nm and 20-30 nm, respectively, obtained by atomic force microscopy (Digital Instruments Nanoscope IV, Veeco, Plainview, N.Y.).

Porous Pt layers, as the current collector for the PCO working electrode 640 and as the counter electrode 630, were prepared by a combination of Pt paste and reactive sputtering on the PCO film and the opposite PCO-free substrate surface, with thicknesses of 83±4 nm and 159±31 nm, respectively. PtO, thin films were first prepared by reactive magnetron sputtering (Kurt J. Lesker, Clairton, Pa.) at a DC power of 50 W from a two-inch-diameter metal target of 99.99% Pt (ACI Alloys, San Jose, Calif.) under controlled argon/oxygen (3/7) atmosphere. Pt paste was applied on the top of the sputtered PtOₓ layer except in the center area of the non-stoichiometric oxide PCO layer 620 to form the working electrode 640, which was reserved for the mechanical response measurements (i.e., the region where the probe tip rested on the film surface). Pt paste was also applied to the outer perimeter of the YSZ substrate to serve as the reference electrode. Then, the samples were annealed at 750° C. in air for 2 hours with a heating and cooling rate of 2° C./min. During this annealing step, PtOₓ was reduced to Pt, resulting in a porous film structure. The sputtered porous Pt layer was used to provide a thin layer with controlled thickness in the area for the mechanical measurement in addition to enhancing adhesion between the Pt paste and ceramic surfaces. There was no evidence of film delamination, as confirmed by subsequent FIB milling to expose the film/electrolyte interfaces for all samples used in experiments described herein.

### Operation of an Oxide Actuator

FIG. 6B illustrates operation of the actuator 600 shown in FIG. 6A using electrical control of chemical expansion or “electrochemical breathing.” The electrical control of chemical expansion is implemented through the “pumping” of oxygen into and out of the nonstoichiometric oxide layer 620 (e.g., PCO film) grown on the ionically conducting substrate 610. As shown in FIG. 6B, a bias voltage V1 applied to the non-stoichiometric oxide layer 620, through the electrode 640, with respect to the counter electrode 630, can cause the non-stoichiometric layer 620 to expand or contract due to changes in oxygen vacancy exchange between the non-stoichiometric oxide layer 620 and the conductive substrate layer 610. The volume change in the non-stoichiometric layer 620 can result in interfacial mechanical stress and/or mechanical strain at the interface between the non-stoichiometric layer 620 and the conductive substrate 610. The mechanical stress at the interface can result in a displacement or a substrate deflection as shown in FIG. 6B. The displacement or change in thickness in the non-stoichiometric layer 620 can be measured using a depth sensing probe 660, as illustrated in FIG. 6B.

In some embodiments, a reference voltage V2 can be applied to the ionically conductive substrate layer 610, through the reference electrode 650, as indicated in FIG. 6B. The reference electrode 650 can also be used to correlate the measured change in thickness in the non-stoichiometric layer 620 with the applied bias voltage V1.

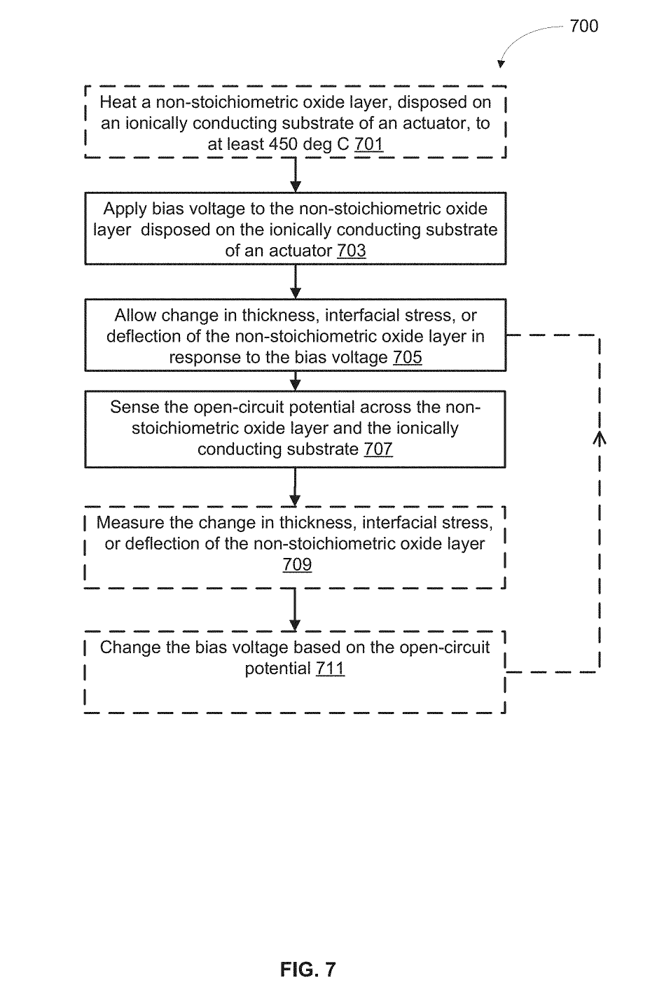

FIG. 7 illustrates an example actuation process 700. This process 700 exploits electrical control of mechanical stress and or mechanical strain between the non-stoichiometric layer and the conductive substrate layer of a non-stoichiometric oxide actuator, such as the actuator 600 shown in FIGS. 6A and 6B. Non-stoichiometric oxide actuators like the actuator 600 described above are capable of functioning at high-temperatures above 450° C. (e.g., 500° C., 550° C., 600° C., 650° C., and so on). Accordingly, the process 700 includes an optional step 701, indicated by dashed lines, of heating or keeping the actuator at a temperature of at least 450° C., e.g., by placing the actuator in a high-temperature environment.

The process 700 includes the step 703 of applying a bias voltage to the non-stoichiometric oxide layer of the actuator, through the electrode in contact with the non-stoichiometric oxide layer. For example, this step 703 can include the application of bias voltage V1 as described with respect to FIG. 6B. The applied bias voltage causes a desired change in oxygen content in the non-stoichiometric oxide layer resulting in the change in thickness, interfacial stress, or strain desired in the actuator. For example, the bias voltage to be applied can be determined to cause the layer of non-stoichiometric oxide 620 to exhibit an out-of-plane strain of up to about 0.5%. As another example, the bias voltage to be applied can be determined to cause the layer of non-stoichiometric oxide 620 to exhibit a deflection of a desired degree or amount in at least a portion of the ionically conductive substrate.

In some embodiments of the actuator used, the applied bias voltage can be from about 40 mV to about 200 mV. In some embodiments, the applied voltage can be as high as a few volts. While tens of millivolts can be used for the tested cases, other designs (e.g., with different film thicknesses or film compositions) could use more voltage, and as much as a few volts is reasonable. Even at voltages of a few volts, there actuation voltages are still lower than alternative actuator materials, such as piezoelectrics. In some embodiments, the reference electrode can be used to apply a reference voltage to the ionically conductive substrate through the electrode in contact with the ionically conductive substrate.

At step 705, the non-stoichiometric layer is allowed to change in thickness, resulting in interfacial stress, or deflection of the non-stoichiometric oxide layer in response to the bias voltage. In some instances of the process 700, the change in thickness of the non-stoichiometric layer can result in a change in mechanical strain as described in examples below. In some embodiments, the adherence of the film of the non-stoichiometric oxide layer to the ionically conductive substrate constrains in-plane chemical strain produces interfacial stress that can be sufficient to induce detectable deflection.

At step 707, the open circuit potential is sensed is between the reference and the working electrode. This can be done using the potentiostat function of an impedance analyzer. The desired bias voltage targets are based on the equations above relating effective pO2 to electrical potential.

In optional step 709, the change in thickness induced in step 705 by the application of bias voltage in step 703 can be measured directly, using any suitable method. For example, the change in thickness, and the resulting interfacial stress and/or strain can be measured using a depth sensing probe positioned appropriately with respect to the non-stoichiometric layer, as indicated in an example configuration in FIG. 6B.

Following the optional step 709 of measuring the induced change in thickness, at optional step 711, the bias voltage can be changed to a desired level based on the open-circuit potential measured at step 707. For example, upon measuring the open-circuit potential at 707, using this open-circuit potential as a feedback signal, if a greater change in thickness is desired, an increased amplitude of bias voltage can be applied, following which steps 705 to 709 can be repeated. Similarly, any additional change in thickness and resulting actuation of the actuator can be achieved through a change in applied bias voltage potential as in step 711.

Example Experiments with Oxide-Based Actuators
Actuation with a Film of PCO

Example experiments of actuation were conducted using a high-temperature, non-stoichiometric oxide actuator like the actuator 600 shown in FIGS. 6A and 6B. Films of PCO with deposited thickness t_{f} ranging from 300-1000 nm approximately 8×8 mm in plane dimensions were grown on YSZ single crystal substrates (1 mm thickness) and were fabricated with a three-electrode configuration with porous Pt reference and counter electrodes. A depth-sensing probe was used to measure the change in thickness of the PCO film and the resulting actuation. The probe rested in contact with the PCO sample surface, with the sample maintained at a constant temperature ranging from 550° C. to 650° C. A bias V1 was applied to the working electrode, in contact with the PCO film, with respect to the reference electrode modulating the oxygen activity in the PCO film, causing oxygen vacancies to be pumped in and out of the film through the YSZ substrate. This in turn lead to a mechanical response that is the result of a combination of PCO film volume change and substrate deflection due to PCO chemical expansion, detectable through probe displacement.

Control samples were made lacking only the PCO film and were prepared to decouple the response of the PCO film from that of the ionically conductive substrate and Pt electrodes. Some example actuators, such as actuator 800 described below, were made with smaller in-plane PCO film dimensions (3 mm diameter) with respect to the YSZ substrate and prepared to decouple out-of-plane strain from deflection.

### Measurements of Actuation

To quantify film “breathing” and mechanical deflection due to reversible oxygen uptake within PCO thin films, the probe-based approach described above was employed and was capable of nanometer-scale displacement measurement at temperatures up to 650° C. A film of up to micrometer-scale thickness was electrically biased with voltages of about 100 mV to drive oxygen content changes within the entire film by adjusting the Nernst electrochemical potential. The corresponding strain ε arising from the change in non-stoichiometry Δδ follows the chemical expansion coefficient of PCO (0.087) defined in Eq. 11:

ε=α_{c}Δδ (11)

PCO film adherence to the YSZ substrate constrained in-plane chemical strain to produce interfacial stress that can be sufficient to induce detectable deflection. This coupling of electrical bias and mechanical displacement enabled demonstration of actuation under conditions of extreme operating environments to quantify mechanisms controlling the extent and rate of film “breathing.” FIG. 6B illustrates the PCO film configuration and measurement at constant elevated temperature.

During mechanical measurements, the position-sensing probe 660 was placed in contact with the surface of the PCO film 620 surface as an electrical bias was applied to the working electrode 640 with respect to the reference electrode 650 (FIG. 6B), and the mechanical displacement was detected as a combination of film thickness change and substrate deflection. Positive applied bias caused negative probe displacement as the film contracted, while a reduction in bias produced concomitant, reversible film expansion and positive probe displacement. This oxide film contraction under positive bias was expected from the pO_{2,eff} in the film given by Eq. 8 above. There can be an asymmetry in magnitude of mechanical response which is explained by the asymmetry in defect concentration change with respect to applied bias: PCO tends toward stoichiometry (δ→0) under more oxidizing conditions and toward δ=0.05 for more reducing conditions.

The reversible, nanometer-scale mechanical response detected in the PCO film samples and the lack of response detected in the control samples devoid of the PCO film showed there was little to no detectable contribution to the measured mechanical response from dimensional changes in the substrate, counter-electrode, or current collector. Curvature of the film/substrate system was detected by acquiring measurements at multiple surface locations with mm-scale lateral spacing relative to the film center. Therefore, the dynamic actuation was caused by concurrent increased PCO film thickness and positive substrate curvature due to interfacial stress.

The probe-based approach to measure film expansion was a versatile and accessible approach. It could be applied to measure both strain-only displacement and displacements amplified by substrate deflection. Furthermore, this method required no particular knowledge of the optical properties of samples, nor did it require samples to have specific optical properties (e.g., reflectivity) as required for other curvature-based techniques. The probe-based method could measure displacements and volumetric expansion resulting from mechanisms other than lattice strain (e.g., grain boundary mediated effects). Unlike dilatometry, this method can be applied to thin film samples, and had finer spatial resolution as compared to most dilatometers.

### Strain-Only, Oxide-Based Actuation

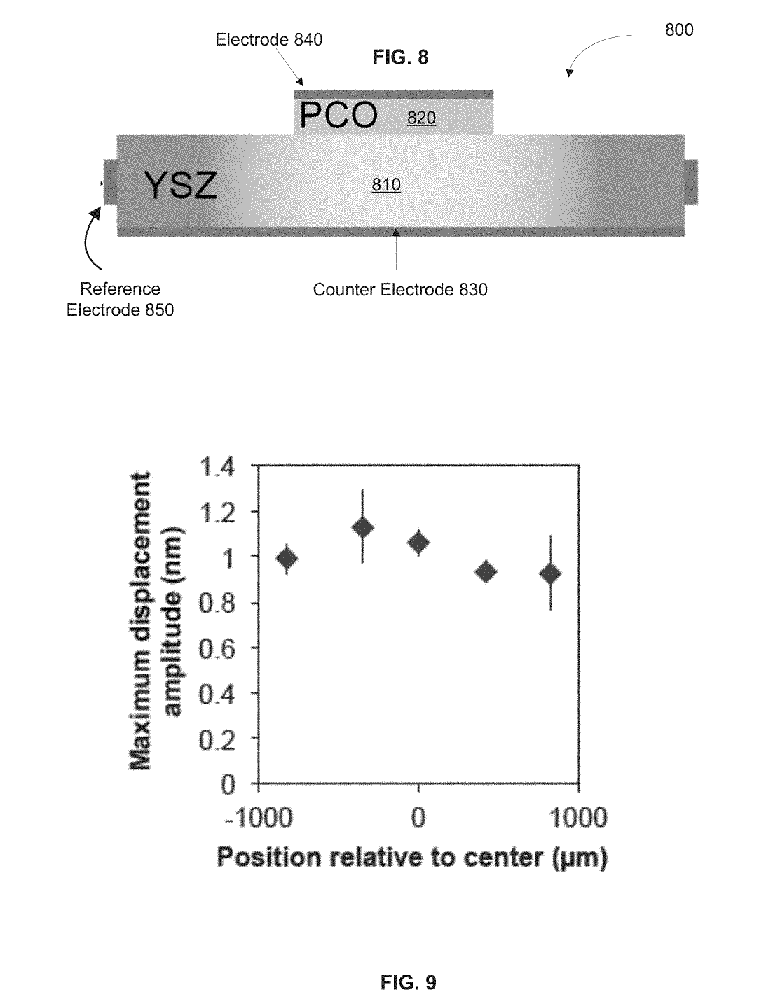

FIG. 8 shows a high-temperature non-stoichiometric actuator 800 that exhibits strain-only displacement. This strain-only actuator 800 has a non-stoichiometric oxide layer 820, an ionically conductive substrate 810, electrodes 840 and 830, and a reference electrode 850. The area of the non-stoichiometric oxide (e.g., PCO) film 820 is smaller than the area of the substrate 810, which means that the oxide film 820 extends over less than the entire surface of the substrate 810. In other words, a portion of the substrate's upper surface is exposed as shown in FIG. 8. Some example actuators used in experiments had PCO films of 3 mm diameter, and ˜1 μm thickness as measured by profilometry. This prevented the film from developing enough interfacial stress under electrical-bias-stimulated chemical expansion to induce substrate deflection. Actuation was conducted following a process similar to the process 700 described in FIG. 7.

### Experimental Measurement of Strain-Only Actuation

FIG. 9 shows the measurements of displacement, resulting from strain-only actuation, as a function of measurement position, relative to the center, along the width of the non-stoichiometric layer 820. As shown in the plot in FIG. 9A, a displacement amplitude of 1 nm was measured consistently across the width of the film, with no sign of curvature due to substrate deflection. In other words, the measured displacement amplitude for a ˜1 μm film with reduced area (3 mm diameter) grown on a 1.5 mm-thick substrate was consistently 1 nm across the width of the film, indicating the absence of substrate deflection under electrically stimulated chemical expansion.

### Deflection by Oxide-Based Actuation

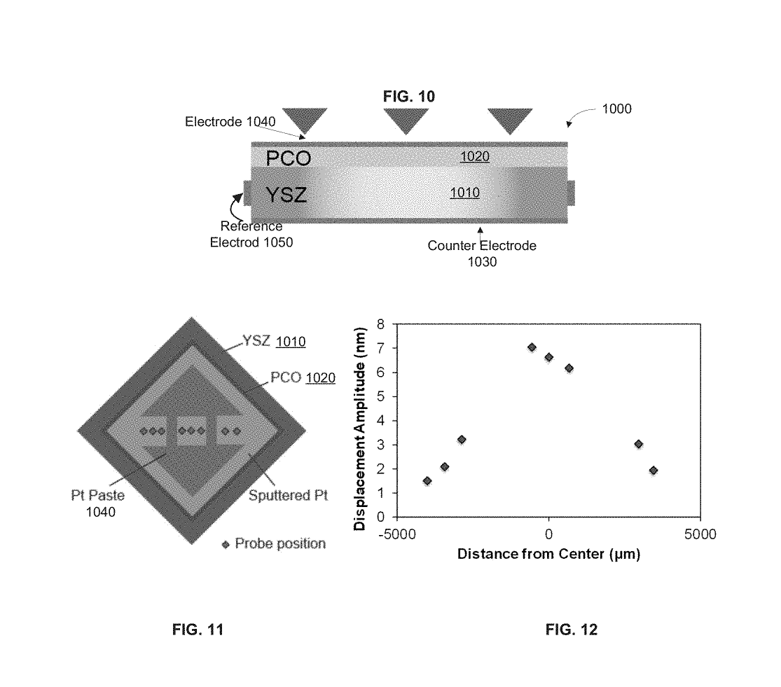

Example actuators like the actuator 600 described above were used to conduct experiments to characterize the deflection from application of bias voltage. To confirm that samples were deflecting in response to applied electrical bias, sample actuators with specific surface geometry were used. An example actuator 1000 is shown in FIGS. 10 and 11, illustrating the sample geometry and probe positions for testing deflection amplitude as a function of position across the sample surface. For example, a 600 nm film of PrₓCe₁₋ₓO_{2-δ} (PCO) was grown on a 1 mm-thick YSZ substrate. The surface electrode was a sputtered layer of porous Pt. Pt paste was also added to improve connectivity of the surface electrode in regions where probe contact would not be necessary. Probe contact positions are illustrated by the inverted triangles in FIG. 10. FIG. 11 illustrates a top view of the actuator 1000 overlaid by indicators of positions of a depth-based probe.

### Experimental Measurement of Deflection-Based Displacement

Deflection amplitude at positions near and far from the center or the clamped sample edges were tested. For each test, a bias voltage of ±128 mV was applied, and magnitudes of equilibrium displacement amplitude D₀ were determined. FIG. 12 shows a plot of equilibrium deflection amplitude D₀ as a function of lateral probe position, indicating increased deflection near sample center as compared to sample edges, confirming curvature upon application of electrical bias signal. D₀ was about a factor of five higher in the sample center than near the sample edges; this indicated sample curvature during the measurement and confirmed that the substrate deflected as the film responded to the applied bias.

As a coarse estimate of expected deflection at the sample center, Stoney's formula predicts a D₀ of 42 nm for a PCO film of 600 nm thickness at 650° C. subjected to chemical strain amplitude of 0.13% leading to interfacial stress amplitude estimated at 0.29 GPa. This estimate is based on the following assumed elastic properties for YSZ and PCO: Young's modulus E_{PCO}=150 GPa, Poisson's ratio v_{PCO}=0.33, E_{YSZ}=272 GPa, V_{YSZ}=0.3. The difference from the actually measured D₀ of 7 nm is explained by the fact that the boundary conditions of Stoney's formula are not accurately met by this experimental design (e.g., the sample is mounted to the heated stage with cement, the film only covers 64% of the substrate area, etc.).

### Temperature, Film Thickness and Bias Voltage Effects

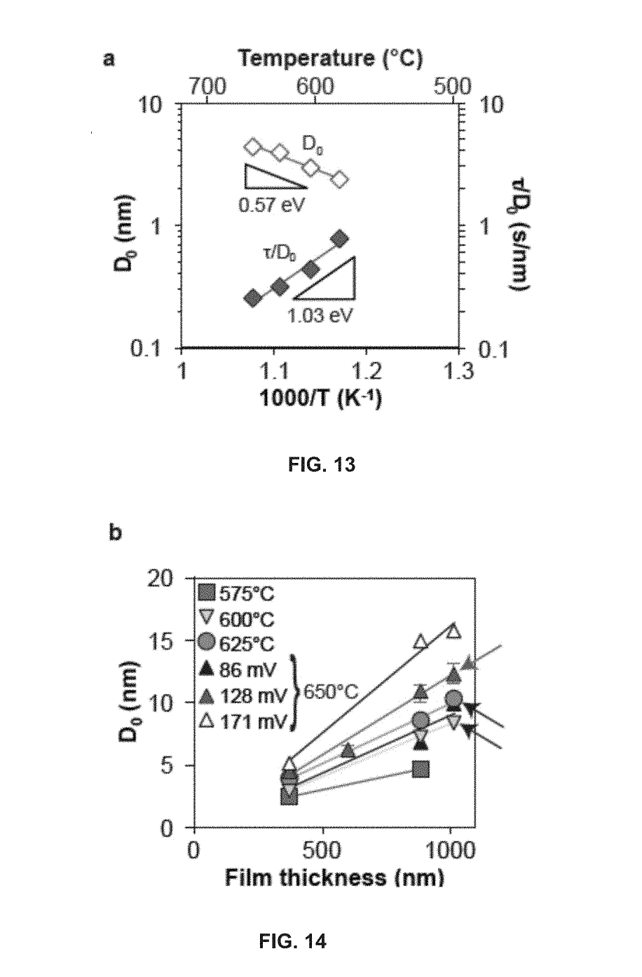

The capacity to rapidly measure these breathing displacements over a wide range of temperatures and bias-modulated defect contents enables determination of the activation energies E_{α} indicative of mechanisms by which oxygen moves in and out of functional oxides. FIGS. 13 and 14 show factors controlling oxide film breathing, including temperature and film thickness, from example experiments conducted using sample actuators with PCO film on YSZ substrate, as described above. PCO generally exhibits increased displacement and decreased phase lag with increased T. In other words, the sample deflection is faster, or activated at higher temperatures.

FIG. 13 shows representative Arrhenius relations from which the activation energies for YSZ diffusion and PCO chemical capacitance modulating the magnitude of mechanical response D₀ and inverse rate of expansion r/D₀ for a given sample and condition were determined. These data were measured for actuators with a PCO film thickness of 371±11 nm. These average E_{α} values were −1.05±0.13 eV (for τ/D₀), and 0.53±0.14 eV (for D₀), reported as mean and standard deviation of at least six measurements across three samples. The same sample actuators at 500° C. to 700° C. were also measured using conventional in situ impedance spectroscopy (IS) which allows for separate measurements of E_{α} associated with electrical impedance between different working electrodes. This showed that the distinct activation energies measured mechanically were consistent with those attributable specifically to the oxygen storage capacity, i.e., chemical capacitance, of the PCO film (E_{α} measured by IS at 0.55±0.07 eV corresponds to displacement magnitude D₀) and to resistance to oxide ion conduction through the YSZ (E_{α} measured by IS at −0.99±0.06 eV corresponds to inverse displacement rate τ/D₀). These activation energies also agreed well with those reported previously for PCO chemical capacitance (0.6 eV) and YSZ diffusion (1 eV).

In the high pO₂ regime investigated here, chemical capacitance in PCO exhibited an activation energy that should correlate with the enthalpy of reaction from Eqs. 1 and 6, shifted by a factor that is dependent on the average oxygen vacancy content δ. In accordance with the derivations given for D₀ and τ/D₀, the good agreement with expected activation energies validated that the calculated maximum breathing displacements D₀ of these oxide films are controlled by the chemical capacitance of the thin film PCO, and that the inverse displacement rate r/D₀ is controlled by the rate of oxygen transport into and out of the PCO film through the YSZ substrate.

FIG. 14 shows a plot of equilibrium magnitude D₀ of probe displacement as a function of film thickness. The displacement magnitude D₀ increases with increasing temperature, applied bias amplitude E₀, and film thickness. These data corresponded to E₀ of 128 and the error bars indicate the range of measured D₀ values for three replicate measurements (All films at E₀=128 mV and T=650° C., highlighted by a red arrow, and all temperatures with E₀=128 mV for the film with thickness 1018±26 nm, highlighted by black arrows). This range was often smaller than the size of the data points.

Comparison with Defect Chemistry Model

Modelling studies were conducted to consider how chemical strain predicted for PCO films subjected to the conditions of the above experiments study related to the displacement amplitude that was experimentally observed. Chemical strain predictions were computed based on the defect modeling information available for PCO using a chemical expansion coefficient of 0.087. As disclosed above, Eq. 6 describes the equilibrium of species for the oxygen vacancy formation reaction in PCO, Eq. 1. Enforcing charge neutrality, mass, and site conservation for the Pr_{0.1}Ce_{0.9}O_{2-δ} composition, (and using values of H_{r,Pr} and kᵣ determined previously), the vacancy concentration expected for this material at each temperature and pO_{2,eff} can be determined, where pO_{2,eff} is determined according to Eq. 8. Based on these data, out-of-plane chemical expansion is predicted by assuming values based on a mechanically constrained film as compared to a freestanding membrane. More specifically, the out-of-plane strain ε_{c,z} is expected to be larger than the predicted strain ΔE of an unconstrained system under the same conditions by an amount described by Eq. 12 below, where v is the Poisson's ratio (˜0.33) and σ₀ is a reference stress.

$${ɛ}_{c , z} = Δ ɛ \frac{1 + v}{1 - v} - \frac{2 v {σ}_{0}}{E} \qquad ( 12 )$$

To determine predicted chemical strain after assuming a reference stress of 0, Eqs. 7 and 12 combine to produce equation 13

$${ɛ}_{c , z} = {α}_{c} Δ δ \frac{1 + v}{1 - v} \qquad ( 13 )$$

Here, v is the assumed Poisson's ratio of 0.33 and Δδ is the change in vacancy content δ with respect to a sample at the testing temperature and ambient pO₂ at 0 mV bias.

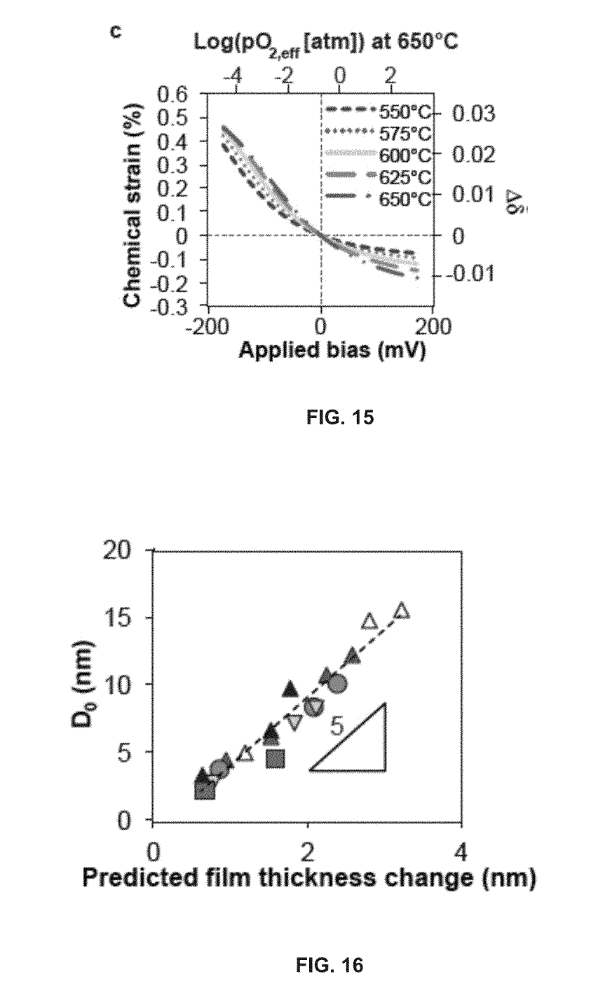

FIG. 15 shows predicted out-of-plane strain ε_{c,z} and non-stoichiometry change Δδ as a function of applied bias at several temperatures for a constrained PCO thin film as predicted by the defect model, with single curves for each temperature and bias condition because these two factors are proportionally related. The pO_{2,eff} values listed on the secondary x-axis are specific to 650° C. FIG. 15 shows that the expected equilibrium strain in these PCO films is 0.2-0.5% depending on applied bias and temperature; this estimate also includes a twofold increase in the strain of a constrained film as compared to a freestanding membrane.

The measurements described above were consistent with expectations shown in FIG. 15 from the PCO defect model: PCO is expected to contract upon a combination of decreased oxide ion vacancy and Pr³⁺ ion concentrations (oxidizing condition, positive bias), and vice versa for increased oxide ion vacancy and Pr³⁺ ion concentrations (reducing condition, negative bias). As the film is driven to expand in-plane, interfacial stress can drive substrate deflection at sufficient stress magnitudes and film lateral dimensions. Indeed, curvature was detectable for films of 8 mm in-plane dimensions as used in experiments described above using films of PCO, while out-of-plane film expansion of ˜1 nm, but not deflection, was detected for a PCO film of ˜1 μm thickness but significantly smaller lateral dimensions at 650° C. Negative substrate curvature amplifies displacement due to film contraction, while positive substrate curvature amplifies film expansion. The observed increases in D₀ caused by increased temperature or applied bias amplitude are also reasonable, in that these factors widen the equilibrium boundaries of accessed vacancy concentration and thus increase the mechanical response. Equilibrium or maximum displacement amplitude is thus proportional to film thickness.

FIG. 16 shows the measured deflection amplitude D₀ against the predicted film thickness change based on chemical strains calculated from FIG. 15 for the set of measurements shown in FIG. 14. A consistent amplification of 5±0.5 nm/nm (ΔD₀/Δε) was observed across all samples, temperatures, and E₀ values, with error determined by bootstrapping as described below.

Specifically, FIG. 14 shows that D₀ was approximately linear with film thickness t_{f}, for different temperatures and applied bias amplitudes, with a vertical intercept at t_{f}=0 of D₀˜±1 nm similar to that detected for control samples (i.e., YSZ substrates with no PCO film). As expected, displacement amplitude increased with increasing temperature at a given applied bias, e.g., up to 12 nm at 128 mV and 650° C. for the 1018 nm film. Further, increasing the amplitude of the applied bias from 128 to 171 mV (increasing pO_{2,eff} range by two orders of magnitude) at a constant temperature of 650° C. increased D₀ of that sample to 16 nm. The observed mechanical response to rapid changes in electrical bias indicates dimensional oscillation in the PCO film that was driven by corresponding changes in oxide ion vacancy content.

### High-Temperature Oxide Actuators

The deflection profile of actuators based on PCO or other non-stoichiometric oxides can be tuned by shifting pO_{2,eff}, which can be accomplished either through changing the gas environment or applying a DC bias. FIGS. 13-16 shows this effect for an example PCO actuator. Referring to FIG. 15, the relationship between Δδ and pO_{2,eff} is nonlinear. However, for higher temperatures and slightly reducing conditions, this dependence can be reasonably approximated as linear. The displacement profiles collected for these conditions reflect the asymmetry in Δδ vs. pO_{2,eff}. The oxidizing (positive) bias condition exhibits less displacement than the reducing (negative) bias condition. This is because the PCO film's oxygen content saturates in highly oxidizing conditions—at some point, the film cannot absorb additional oxygen, and ceases to contract. In contrast, on the reducing side of the plot, PCO is not limited in this way for the range of pO_{2,eff} used during these experiments, and therefore doesn't reach a plateau in δ. (However, in the reducing direction the oxygen content may eventually reach a plateau upon full reduction of the Pr cations.)

The stress exerted by such film expansion of the actuator can be estimated, and the associated force generated can be measured and can be designed through geometry of the device parameters, such as film thickness and boundary conditions. The stress generated from a this type of nonstoichiometric oxide film expansion strain of 0.1 to 0.5% is approximately 0.2 to 1.4 GPa, estimated as the product of this strain and the Young's modulus of the oxide as 150-270 GPa.

### Quantification of Performance Using Lissajous Plots

The Lissajous plot, which is a way to visually compare periodic signals, is a useful construction for understanding these kinds of effects. If two signals of interest A and B overlap and are completely in phase, then a Lissajous plot of A vs. B will appear as a straight line with a slope corresponding to the unit conversion (amplitude ratio) between A and B. If A and B have the same symmetry and frequency (e.g., sine waves with a fixed frequency) but are out of phase, then the Lissajous plot will be an oval with an area correlating with the size of the phase lag. If two signals have different symmetry and the same frequency, then these differences will be apparent in the Lissajous plot as peaks, plateaus, and other deviations from the ovoid symmetry. It is this third case that is most interesting for the current discussion.

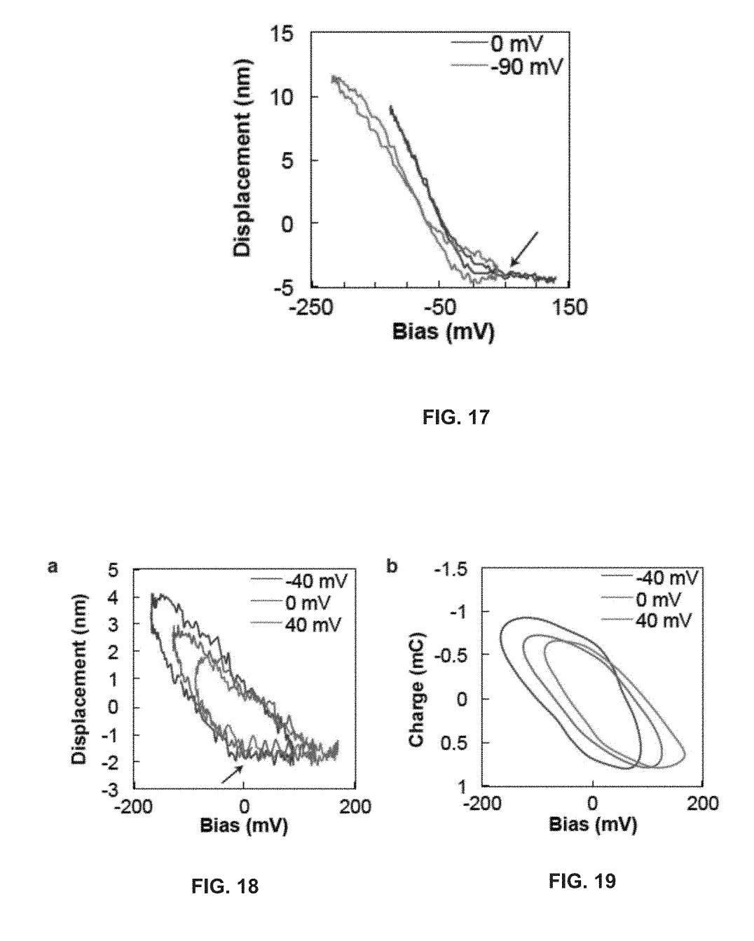

FIG. 17 shows Lissajous plots of displacement vs. applied bias for two V_{offset} conditions. These experiments were conducted on the sample with film thickness 600 nm at 650° C., with a sinusoidally varying applied bias with an amplitude of 128 mV centered around a DC offset voltage of 0 or −90 mV. When V_{offset} was 0 mV (oxidizing condition), there was a distinct plateau in the displacement signal for positive biases that is indicative of film saturation. In contrast, when pO_{2,eff} was shifted by about two orders of magnitude in the reducing direction (V_{offset}=−90 mV), this plateau largely disappeared and a more symmetric displacement vs. bias profile resulted. Additionally, the total displacement amplitude increased with the reducing V_{offset} because of the additional capacity accessed in that condition.

The pair of Lissajous plots in FIG. 17 (averaged over ten cycles at 0.05 Hz) of displacement vs. voltage for a film subjected to two conditions of DC bias V_{offset} (V_{offset}±128 mV, where V_{offset}=0 and −90 mV) at 650° C. Considering first the case of V_{offset}=mV, there was a clear displacement plateau for positive (oxidizing) bias, indicative of the oxygen saturation described above. However, applying a constant DC bias of −90 mV (roughly two orders of magnitude pO_{2,eff}) produced a more symmetric profile, with a larger total displacement amplitude and a minimal displacement plateau at either extreme. Thus, a way to tune the deflection profile of a high-temperature oxide actuator is demonstrated—by shifting the effective pO₂ through applying DC bias or changing the operando gas environment. This has two implications, among others. First, the operando gas environment may be an important parameter when designing high temperature oxide actuators, because different materials may exhibit linear defect chemistry vs. applied voltage for different pO₂ regimes, and low power operation conditions will favor those materials that require minimal DC potential. Second, these oxide materials are also useful as oxygen sensors, including for actuation in response to changes in oxygen partial pressures. With reference to gas composition sensors based on Nernst electrical potentials generated by difference in pO₂, here the gas composition can also produce a mechanical signal—with implications for non-electronic, non-contact sensor architectures.

Actuators with Perovskite SrTi_{0.65}Fe_{0.35}O_{3-δ} (STF) Oxide Layers

Other suitable materials for oxide-based actuators include SrTi_{0.65}Fe_{0.35}O_{3-δ} (STF), a model perovskite-structured oxide. Like PCO, STF is a mixed ionic-electronic conducting oxide for which extensive bulk defect models are available to predict defect chemistry under a range of oxygen partial pressures and temperatures. However, STF has several key distinctions from PCO including a tendency to exhibit compositional instability in the form of Sr segregation at high temperatures, a somewhat smaller chemical expansion coefficient (only ˜0.04 instead of 0.087), and for thin films, a large pO₂-independent capacitance identified by impedance spectroscopy that is not well-explained by a single defect model. Additionally, at ambient atmospheres, STF maintains a large enough oxygen vacancy concentration that it may be more readily oxidized than PCO, producing a more symmetric displacement response to applied bias.

From experimental observations, high-temperature oxide actuation can be carried out in the STF system, an alternative system to PCO, and such electrochemically-induced actuation could be tuned. In example experimental conditions, 300 nm films of STF were grown by pulsed laser deposition on 0.5 mm YSZ substrates. The thinner substrate enabled appreciable displacement detection despite the smaller chemical expansion coefficient and film thickness for STF. Additionally, the characteristic times measured for the mechanical response of the STF films were generally faster for the same reason. Bulk models of STF predict slightly decreased chemical expansion for the same change in applied bias with increased temperature, a trend that was reproduced in the experimental data. The time constant, in contrast, was significantly affected by temperature; this is because increased temperature activates the rate-limiting oxide ion diffusion step in the YSZ substrate.

Based on available defect models for STF, shifting to an oxidizing pO_{2,eff} ought to enhance the amplitude of the mechanical displacement response. However, the opposite was observed for the deflection data. Without being bound by any particular theory, there are a few possible explanations for this: (i) the defect model does not accurately predict defect chemistry in the high pO₂ regime, (ii) the chemical expansion coefficient in the high pO₂ regime is smaller than elsewhere for the same changes in defect content, or (iii) a leakage current present in the high pO₂ regime prevents the full reversible expansion effect from being realized. In principle, combinations of these three explanations are also possible. Comparing the displacement Lissajous profiles to the charge Lissajous profiles gives some insight into the source of this discrepancy.

FIGS. 18 and 19 present this comparison for three conditions of pO_{2,eff}. Like for PCO, the STF displacement profile exhibited an oxygen-saturation plateau on the positive-bias side of the plot, which was mostly mitigated by a small DC bias of −40 mV. In contrast, the charge Lissajous plots showed a minimal plateau effect for the same regions. This means that for positive biases, charge continued to flow into the electrochemical cell without producing a mechanical signal.

FIG. 18 shows Lissajous plots of displacement and FIG. 19 shows Lissajous plots of charge vs. applied bias for three V_{offset} conditions. These experiments were conducted at 630° C., with an applied bias amplitudes of 128 mV centered around 0, 40, or −40 mV. When V_{offset} is 40 mV (oxidizing condition), there is a slight plateau in the displacement signal for positive biases that is indicative of film saturation. However, this effect is much less severe than for the PCO films in FIG. 17. When pO_{2,eff} is shifted in the reducing direction (V_{offset}=−40 mV), this plateau largely disappears and a more symmetric displacement vs. bias profile results, along with a slight increase in the total displacement amplitude. Comparing the charge and displacement Lissajous plots, the plateau effect at positive biases is not apparent for the charge plots, or that the displacement is not necessarily proportional to charge flow. This indicates that there must be a charge storage mechanism in the STF sample that is not coupled to volume change.

The charge and displacement Lissajous plots in FIGS. 18 and 19 were both constructed from flattened data, meaning that leakage current and signal drift, respectively, were removed already. Therefore, this provides an example where charge storage (or capacitance) is not linearly coupled to chemical expansion. This could result from a change in the defect chemistry of the oxide at high pO_{2,eff}, or a different charge storage mechanism (such as an interfacial capacitance).

The material selection between the examples described here, PCO and STF, impacts the high temperature oxide actuator's linearity in different ranges of pO_{2,eff}. In oxidizing conditions, STF will produce a more linear displacement vs. ΔE than PCO. However, PCO has a generally larger α_{c}, meaning that it can produce larger strains vs. ΔV.

### CONCLUSION

Described above are embodiments of high-temperature non-stoichiometric oxide actuators and methods of actuations, using electrical control over chemical expansion on non-stoichiometric oxide materials. Also described is a method of measuring the changes induced in the non-stoichiometric oxide layer of the actuator. Example actuators based on the non-stoichiometric layer being PCO and STF are described and other suitable material are disclosed.

The PCO actuators described here are examples; there are many chemomechanically coupled non-stoichiometric oxides that can operate according to the same principles, and even some that can combine the chemical expansion effect with a larger magnitude strain resulting from bias-induced phase change. Furthermore, this actuator design has the advantage of non-volatile mechanical memory: if leakage is sufficiently limited (e.g., by blocking gas exchange), the device may be “frozen” in place upon disconnection of the circuit that permits ionic mobility. This opens up a new design space of high-temperature, low voltage micro-electromechanical systems based on a mechanism that couples electrical signals to mechanical stress and strain via material defect chemistry. Devices based on this alternative actuation mechanism are expected to be of interest to the design of robotics in extreme environments ranging from nuclear power plants to turbine engines to spacecraft.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An actuator comprising:
an ionically conducting substrate;
a layer of non-stoichiometric oxide disposed on the ionically conducting substrate;
a first electrode, in electrical communication with the ionically conducting substrate, to reduce gas-phase oxygen molecules to oxygen ions and to pump the oxygen ions through the ionically conducting substrate into the layer of non-stoichiometric oxide, the oxygen ions causing a change in thickness of the layer of non-stoichiometric oxide;
a second electrode, in electrical communication with the layer of non-stoichiometric oxide, to at least partially block the layer of non-stoichiometric oxide from emitting the oxygen ions; and
a reference electrode, in electrical communication with the ionically conducting substrate, to sense an open-circuit potential between the first electrode and the second electrode, the open-circuit potential representing a gradient in oxygen pressure between the first electrode and the second electrode.

2. The actuator of claim 1, wherein the ionically conducting substrate comprises yttria stabilized zirconia.

3. The detector of claim 1, wherein the ionically conducting substrate has a thickness of about 50 μm to about 10 mm.

4. The actuator of claim 1, wherein the layer of non-stoichiometric oxide comprises at least one of PrₓCe₁₋ₓO_{2-δ}, CeO_{2-δ}, Sr(Ti,Fe)O_{3-δ}, (La,Sr)(Co,Fe)O_{3-δ}, or LaMnO₃.

5. The actuator of claim 1, wherein the layer of non-stoichiometric oxide has a thickness of about 50 nm and about 1 μm when the bias voltage is 0 volts.

6. The actuator of claim 1, wherein the layer of non-stoichiometric oxide exhibits an out-of-plane strain of up to about 0.5%.

7. The actuator of claim 1, wherein the layer of non-stoichiometric oxide has a width different than a width of the ionically conducting substrate.

8. The actuator of claim 1, wherein the layer of non-stoichiometric oxide is chemically and physically stable at a temperature of 450 degrees Celsius.

9. The actuator of claim 1, wherein the change in thickness is due to a strain-only expansion.

10. The actuator of claim 1, wherein the change in thickness is about 0.25 nm to about 5 nm.

11. The actuator of claim 1, wherein the first electrode comprises at least one of a porous metal or a mixed conductor.

12. The actuator of claim 1, wherein the reference electrode is disposed about a circumference of the ionically conducting substrate.

13. The actuator of claim 1, wherein the first electrode and the reference electrode are disposed on a surface of the ionically conducting substrate.

14. A method comprising:
applying a bias voltage to a layer of non-stoichiometric oxide disposed on an ionically conducting substrate, the bias voltage causing a change in oxygen content of the layer of non-stoichiometric oxide, the change in oxygen content of the layer of non-stoichiometric oxide causing a change in at least one of a thickness, interfacial stress, or deflection of the layer of non-stoichiometric oxide; and
sensing an open-circuit potential across the layer of non-stoichiometric oxide and the ionically conducting substrate.

15. The method of claim 14, wherein applying the bias voltage comprises applying a bias voltage of about 10 millivolts to about 10 volts.

16. The method of claim 14, wherein applying the bias voltage causes the layer of non-stoichiometric oxide to exhibit an out-of-plane strain of up to about 0.5%.

17. The method of claim 14, wherein applying the bias voltage causes the layer of non-stoichiometric oxide to bend at least a portion of the ionically conducting substrate.

18. The method of claim 14, wherein the change in thickness is due to a strain-only expansion.

19. The method of claim 14, wherein the change in thickness is at least about 1 nm.

20. The method of claim 14, further comprising:
changing the bias voltage based on the open-circuit potential.

21. The method of claim 14, further comprising:
heating the layer of non-stoichiometric oxide to a temperature of at least about 450 degrees Celsius.

22. An actuator comprising:
an ionically conducting substrate;
a layer of non-stoichiometric oxide disposed on the ionically conducting substrate, the layer of non-stoichiometric oxide being chemically and physically stable at a temperature of 450 degrees Celsius; and
a pair of electrodes to apply a bias voltage across the layer of non-stoichiometric oxide and the ionically conducting substrate, the bias voltage causing a change in oxygen content of the layer of non-stoichiometric oxide, the change in oxygen content of the layer of non-stoichiometric oxide causing a change in at least one of a thickness, interfacial stress, or deflection of the layer of non-stoichiometric oxide.

23. An actuator comprising:
an ionically conducting substrate;
a layer of non-stoichiometric oxide disposed on the ionically conducting substrate, the layer of non-stoichiometric oxide comprising a fluorite-structured oxide; and
a pair of electrodes to apply a bias voltage across the layer of non-stoichiometric oxide and the ionically conducting substrate, the bias voltage causing a change in oxygen content of the layer of non-stoichiometric oxide, the change in oxygen content of the layer of non-stoichiometric oxide causing a change in at least one of a thickness, interfacial stress, or deflection of the layer of non-stoichiometric oxide.
